(19) United States
(12) Patent Application Publication
(10) Pub. No.: US 2026/0047122 A1
(43) Pub. Date: Feb. 12, 2026

(54) METHOD FOR FABRICATING SEMICONDUCTOR DEVICE

(71) Applicant: SK hynix Inc., Gyeonggi-do (KR)

(72) Inventor: Jung Gun HEO, Gyeonggi-do (KR)

(21) Appl. No.: 19/096,728

(22) Filed: Apr. 1, 2025

(30) Foreign Application Priority Data
Aug. 7, 2024 (KR) 10-2024-0105417

(51) Int. Cl. H10D 30/01; H01L 21/308; H10D 64/01

(52) U.S. Cl. CPC H10D 30/025; H01L 21/3081; H10D 64/025

(57) ABSTRACT

Disclosed is a method for fabricating a semiconductor device that improves a Self-Aligned Contact (SAC) margin by applying a wave-shaped buried gate. The method includes forming an isolation layer over a substrate and active regions defined by the isolation layer, forming a first hard mask pattern having a protrusion extending in a first direction over the substrate and overlapping with both ends of the active regions, forming a trench having a plurality of concave portions crossing the active regions and the isolation layer in the first direction and overlapping with the active regions by etching the substrate, and forming a buried gate structure to gap-fill the trench. The active regions are disposed in a first direction and a second direction orthogonal to the first direction and tilted in a third direction diagonal to the first and second directions.

### CROSS-REFERENCE TO RELATED APPLICATIONS

The present application claims priority under 35 U.S.C 119(a) to Korean Patent Application No. 10-2024-0105417, filed on Aug. 7, 2024, which is incorporated herein by reference in its entirety.

### BACKGROUND

### 1. Field

Embodiments of the present disclosure relate generally to a method for fabricating a semiconductor device including a buried gate, and more particularly, to a method for fabricating a semiconductor device including a wave-shaped buried gate.

### 2. Description of the Related Art

As semiconductor devices are being miniaturized and highly integrated more and more, methods for realizing fine patterns are being developed. In the existing photolithography process, new exposure equipment and the like are being developed to realize the fine patterns, but there are limitations in realizing patterns with line widths equal to or thinner than a predetermined critical dimension.

### SUMMARY

Embodiments of the present disclosure are directed to a method for fabricating a semiconductor device that improves a Self-Aligned Contact (SAC) margin by applying a wave-shaped buried gate.

In accordance with an embodiment of the present disclosure, a method for fabricating a semiconductor device includes forming an isolation layer over a substrate and a plurality of active regions defined by the isolation layer; forming a first hard mask pattern having a protrusion extending in a first direction over the substrate and overlapping with both ends of the active regions; forming a trench having a concave portion crossing the active regions and the isolation layer in the first direction and overlapping with the active regions by etching the substrate with the first hard mask pattern used as an etching barrier; and forming a buried gate structure to gap-fill the trench, wherein the active regions are disposed in a first direction and a second direction which is orthogonal to the first direction and tilted in a third direction. The third direction may be diagonal to the first and second directions.

In accordance with an embodiment of the present disclosure, a method for fabricating a semiconductor device includes forming a plurality of active regions over a substrate; forming a first hard mask pattern having protrusions extending in a first direction over the substrate and overlapping with both ends of the active regions; forming a trench having a plurality of concave portions overlapping with the active regions; and forming a buried gate structure to gap-fill the trench, wherein the active regions are disposed in first and second directions and are extending in a third direction which is non-orthogonal to the first and second directions.

### BRIEF DESCRIPTION OF THE DRAWINGS

FIGS. 1A, 2A, 3A, 4A, 5A, 6A, 7A and 8A are process plan views illustrating a method for fabricating a semiconductor device in accordance with an embodiment of the present disclosure.

FIGS. 1B, 2B, 3B, 4B, 5B, 6B, 7B and 8B are cross-sectional views taken along a line A-A′ shown in FIGS. 1A, 2A, 3A, 4A, 5A, 6A, 7A and 8A, respectively.

FIGS. 1C, 2C, 3C, 4C, 5C, 6C, 7C and 8C are cross-sectional views taken along a line B-B′ shown in FIGS. 1A, 2A, 3A, 4A, 5A, 6A, 7A and 8A, respectively.

FIGS. 9A to 9I are cross-sectional views illustrating operations of a method for forming a second mask pattern 16A shown in FIG. 2A.

FIGS. 10A to 10G are cross-sectional views illustrating operations of a method for forming a fourth mask layer 19 shown in FIG. 3A.

FIGS. 11A to 11C are cross-sectional views illustrating operations of a method for forming a second mask pattern 16B shown in FIG. 4A.

FIGS. 12A to 12H are cross-sectional views illustrating operations of a method for forming a second hard mask layer 17 shown in FIG. 5A.

FIGS. 13A to 13C are cross-sectional views illustrating operations of a method for forming the first hard mask pattern 14′ of FIG. 6A.

FIG. 14 is a plan view illustrating another embodiment of FIG. 3A.

### DETAILED DESCRIPTION

Embodiments of the present disclosure will be described below in more detail with reference to the accompanying drawings. The embodiments may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

Hereinafter, the various embodiments of the present disclosure will be described in detail with reference to the attached drawings. The drawings are not necessarily to scale and in some instances, proportions may have been exaggerated in order to clearly illustrate features of the embodiments. When a first layer is referred to as being ‘on’ a second layer or ‘on’ a substrate, it not only refers to a case where the first layer is formed directly on the second layer or the substrate but also a case where a third layer exists between the first layer and the second layer or the substrate.

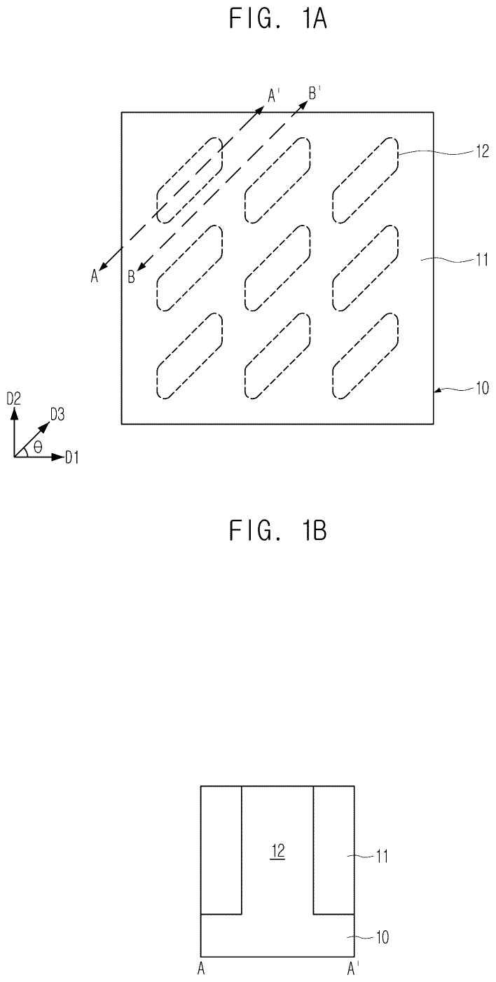

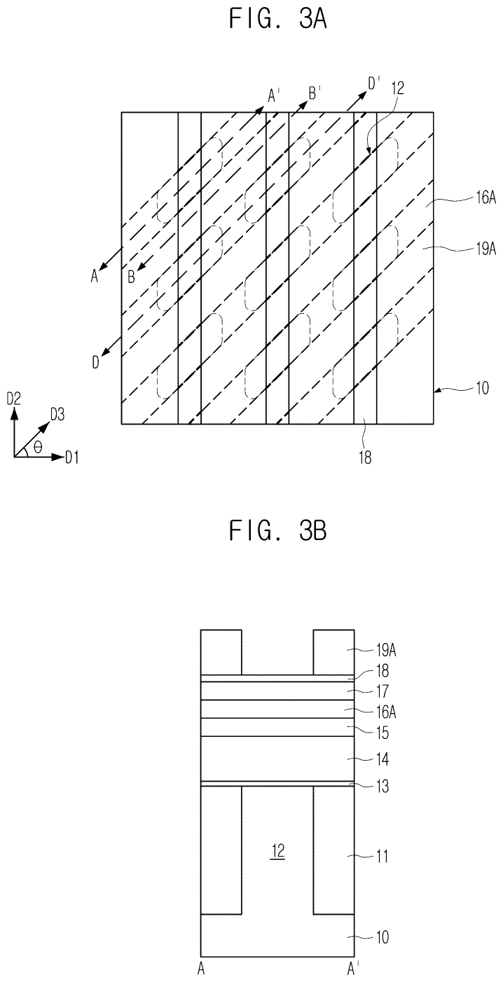

FIGS. 1A, 2A, 3A, 4A, 5A, 6A, 7A and 8A are process plan views illustrating a method for fabricating a semiconductor device in accordance with an embodiment of the present disclosure. FIGS. 1B, 2B, 3B, 4B, 5B, 6B, 7B and 8B are cross-sectional views taken along a line A-A′ shown in FIGS. 1A, 2A, 3A, 4A, 5A, 6A, 7A and 8A, respectively. FIGS. 1C, 2C, 3C, 4C, 5C, 6C, 7C and 8C are cross-sectional views taken along a line B-B′ shown in FIGS. 1A, 2A, 3A, 4A, 5A, 6A, 7A and 8A, respectively. FIGS. A, B, and C of each figure number represent the same process of different viewpoints. FIG. 14 is a plan view illustrating another embodiment of FIG. 3A.

Referring to FIGS. 1A to 1C, an isolation layer 11 may be formed over a substrate 10 to define a plurality of active regions 12 arranged in a first direction D1 and a second direction D2 which is orthogonal to the first direction D1 and tilted in a third direction D3 which is diagonal to the first and second directions D1 and D2.

The substrate 10 may be a material suitable for semiconductor processing. The substrate 10 may include a semiconductor substrate. The substrate 10 may be formed of a material containing silicon. The substrate 10 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 10 may also include another semiconductor material, such as germanium. The substrate 10 may include a III/V-group semiconductor substrate, for example, a compound semiconductor substrate, such as gallium arsenide (GaAs). The substrate 10 may include an SOI (Silicon-On-Insulator) substrate.

The isolation layer 11 may be a Shallow Trench Isolation (STI) region that is formed by a trench etching process. The isolation layer 11 may be formed by filling an isolation trench with a dielectric material. The isolation layer 11 may include silicon oxide, silicon nitride, or a combination thereof.

The active regions 12 may be formed of strips disposed in the form of an array. The array of the active regions 12 may include a row array and/or a column array. The row array of active regions 12 may include active regions 12 that are disposed in rows in the first direction D1. The column array of active regions 12 may include active regions 12 that are disposed in columns in the second direction D2. The longitudinal direction of the active regions 12, i.e., the third direction D3, may be non-orthogonal to the first direction D1and the second direction D2 and may form an intersection angle (θ) with the first direction D1. The intersection angle (θ) between the first direction D1 and the third direction D3 of each active region 12 may range from approximately 10°to 80°, however the technical concepts and scope of the present disclosure may not be limited thereto. The range of the intersection angle (θ) may be affected by such parameters as the area of each active region 12, the line width of the bit line, and the line width of the buried gate structure.

The active regions 12 may be disposed in the third direction D3.

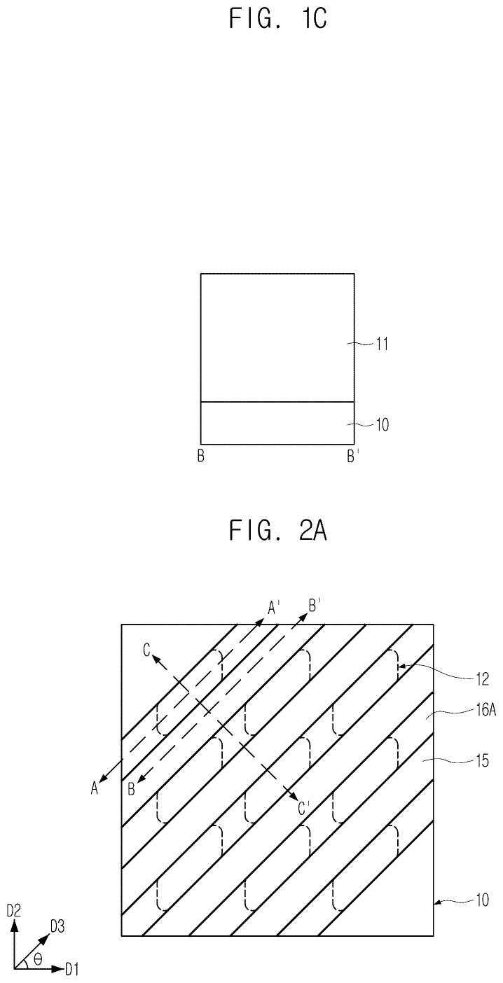

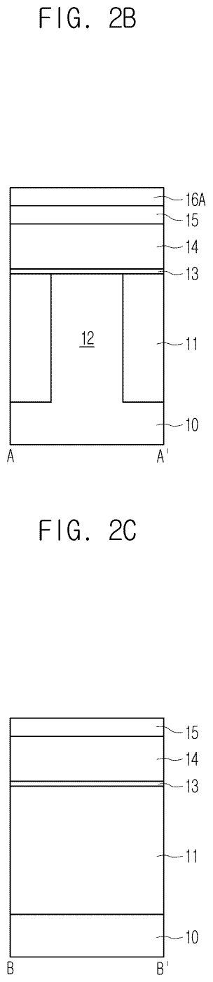

Referring to FIGS. 2A to 2C, an adhesive layer 13, a first hard mask layer 14, a first mask layer 15 and a second mask pattern 16A may be sequentially formed over the active regions 12 and the isolation layer 11.

The adhesive layer 13 may serve to increase the adhesive force between the substrate 10 and the first hard mask layer 14. The adhesive layer 13 may include a dielectric material, such as, for example, an oxide material. The adhesive layer 13 may be formed on the profile of the substrate 10 with a thin and uniform thickness.

The first hard mask layer 14 may function as an etching barrier for etching the substrate 10. The first hard mask layer 14 may include a dielectric material having an etching selectivity with respect to the active regions 12 and the isolation layer 11. For example, the first hard mask layer 14 may include a carbon material. For example, the carbon material may include amorphous carbon.

The first mask layer 15 may function as an etching barrier for etching the first hard mask layer 14. The first mask layer 15 may include a dielectric material having an etching selectivity with respect to the first hard mask layer 14. The first mask layer 15 may be formed to have a thinner thickness than the first hard mask layer 14. For example, the first mask layer 15 may include a nitride material. For example, the nitride material may include silicon nitride.

The second mask pattern 16A may function as an etching barrier for etching the first mask layer 15 and the first hard mask layer 14. The second mask pattern 16A may include a material having an etching selectivity with respect to the first mask layer 15 and the first hard mask layer 14. For example, the second mask pattern 16A may include a silicon material, such as, polysilicon or amorphous silicon.

The second mask pattern 16A may have a line and space shape, which is a structure in which line shapes are repeatedly disposed at regular intervals. The second mask pattern 16A may be tilted and extend in the same diagonal direction as that of the active region 12. The second mask pattern 16A may have a line shape that extends in the third direction D3.

The second mask pattern 16A may have a line width which is equal to the line width of the short axis of the active region 12. The second mask pattern 16A may be formed through Double Spacer Patterning Technology (DSPT). The second mask pattern 16A may have a fine line width that is formed by performing the spacer patterning technology twice.

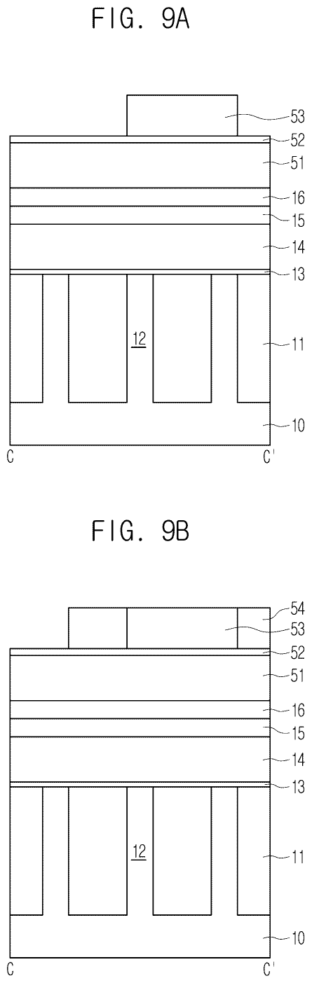

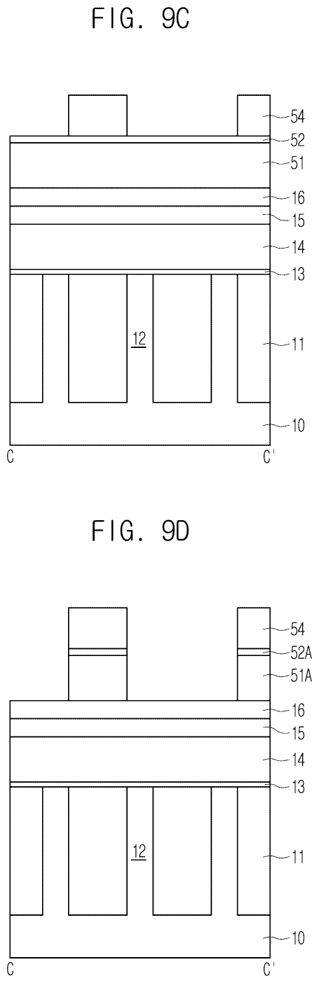

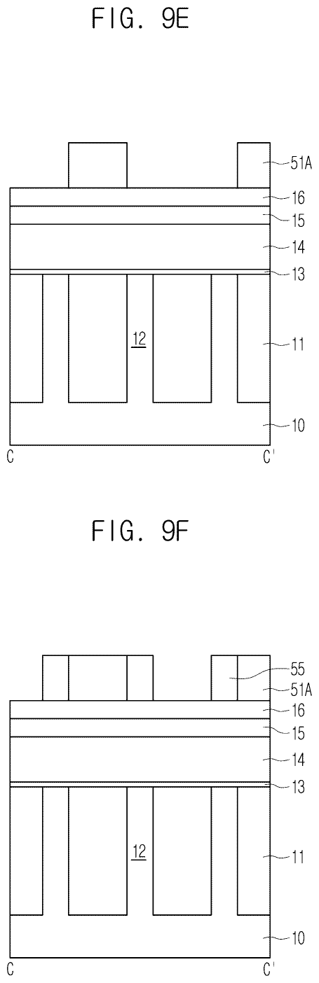

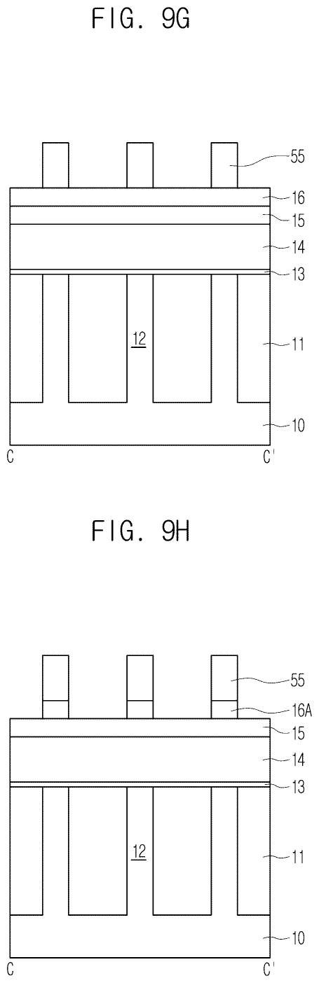

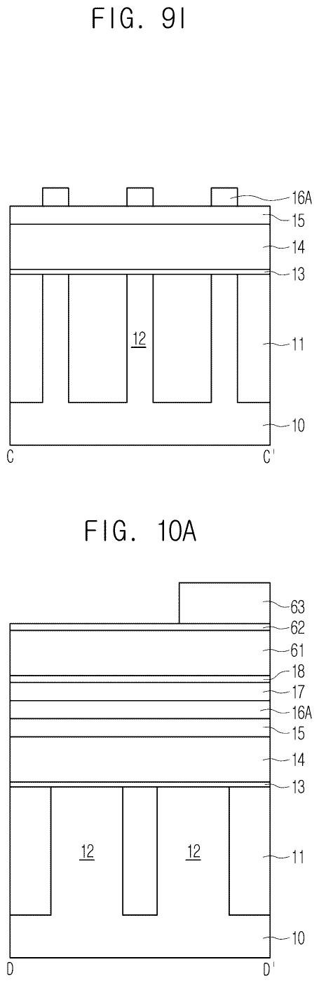

The process of forming the second mask pattern 16A will be described in detail with reference to FIGS. 9A to 9H below.

Since the second mask pattern 16A is not formed in the cross-sectional view taken along the line B-B′ shown in FIG. 2A, the first mask layer 15 may be exposed as it is in the cross-sectional view of FIG. 2C.

Referring to FIGS. 3A to 3C, the second hard mask layer 17 and the third mask layer 18 may be sequentially formed over the second mask pattern 16A and the first mask layer 15.

Subsequently, a fourth mask pattern 19A may be sequentially formed over the third mask layer 18.

The second hard mask layer 17 may be formed over the second mask pattern 16A and the first mask layer 15 to gap-fill the space between the second mask pattern 16A. The second hard mask layer 17 may be referred to as a ‘planarization layer’. The second hard mask layer 17 may function as an etching barrier for etching the second mask pattern 16A. The second hard mask layer 17 may include a material having an etching selectivity with respect to the second mask pattern 16A and the first mask layer 15. For example, the second hard mask layer 17 may include a carbon material. For example, the carbon material may include a Spin-on-Carbon (SOC) material.

The third mask layer 18 may function as an etching barrier for etching the second hard mask layer 17. The third mask layer 18 may include a dielectric material having an etching selectivity with respect to the second hard mask layer 17. The third mask layer 18 may be formed to have a thinner thickness than the second hard mask layer 17. For example, the third mask layer 18 may include a nitride material. For example, the nitride material may include silicon nitride or silicon oxynitride.

The fourth mask pattern 19A may function as an etching barrier for etching the third mask layer 18 and the second hard mask layer 17. The fourth mask pattern 19A may include a material having an etching selectivity with respect to the third mask layer 18 and the second hard mask layer 17. For example, the fourth mask pattern 19A may include a silicon material. For example, the silicon material may include polysilicon.

The fourth mask pattern 19A may have a line shape extending in the second direction D2 and spaced apart in the first direction D1. The area that is open by the fourth mask pattern 19A may partially overlap with the active region 12. The area that is open by the fourth mask pattern 19A may cross the center of the active region 12 in the second direction D2.

According to another embodiment of the present disclosure, the fourth mask pattern 19A may have a line shape extending in the first direction D1 and spaced apart in the second direction D2, as illustrated in FIG. 14.

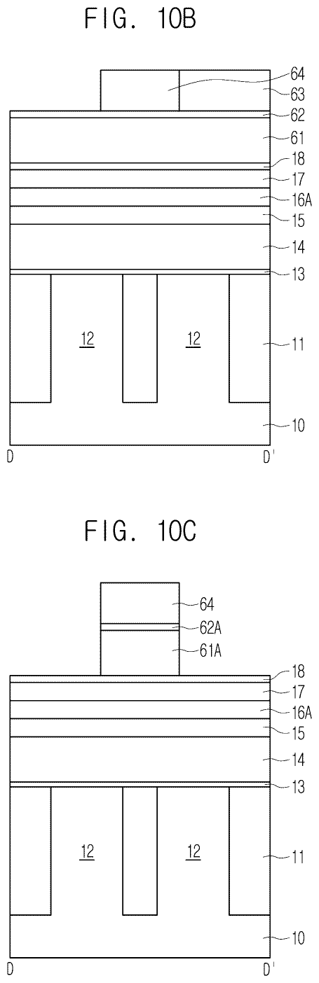

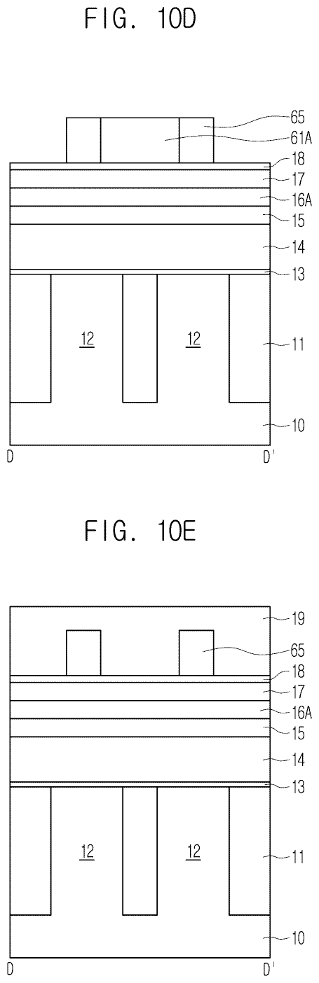

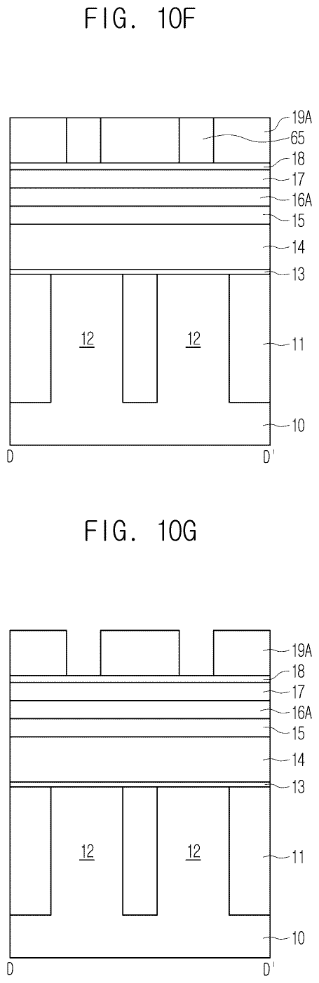

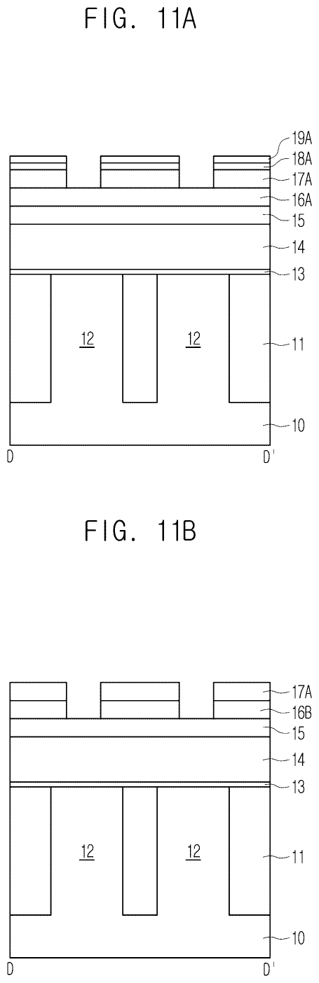

The process of forming the fourth mask pattern 19 will be described in detail below with reference to FIGS. 10A to 10G.

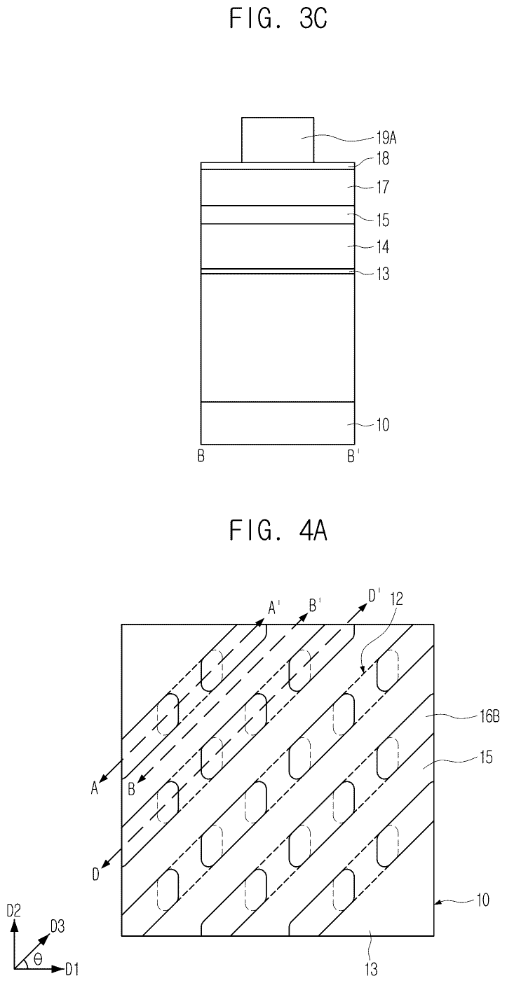

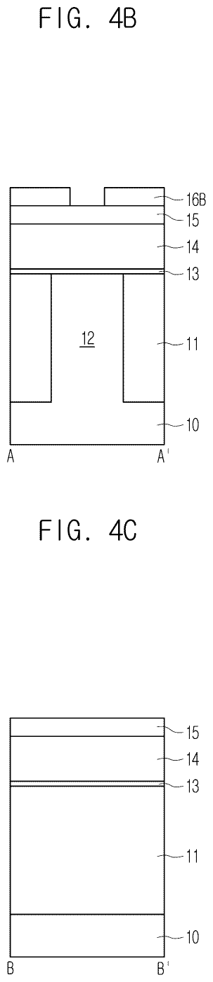

Referring to FIGS. 4A to 4C, an island-shape second mask pattern 16B may be formed.

The second mask pattern 16B may have the same island-shape and size as those of the active region 12. The second mask pattern 16B may partially overlap with the active region 12. More specifically, both ends of the second mask pattern 16B may overlap with the facing ends of the active regions 12 that are disposed adjacently in the third direction D3. The area where the second mask pattern 16B and the active region 12 overlap with each other may be a bonding area for forming a contact in a subsequent process.

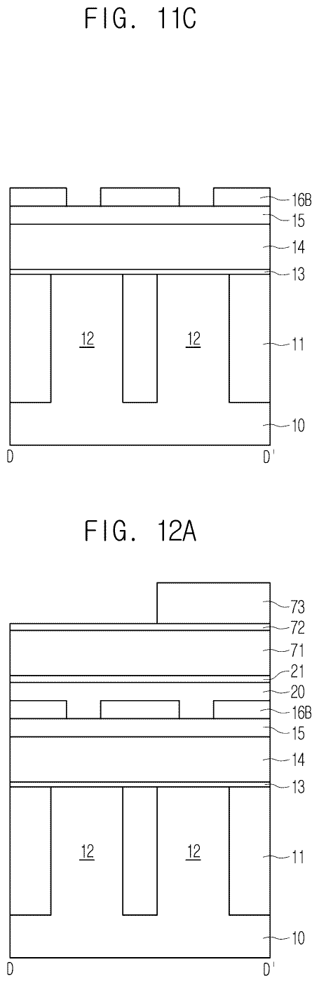

The process of forming the second mask pattern 16B will be described in detail below with reference to FIGS. 11A to 11C.

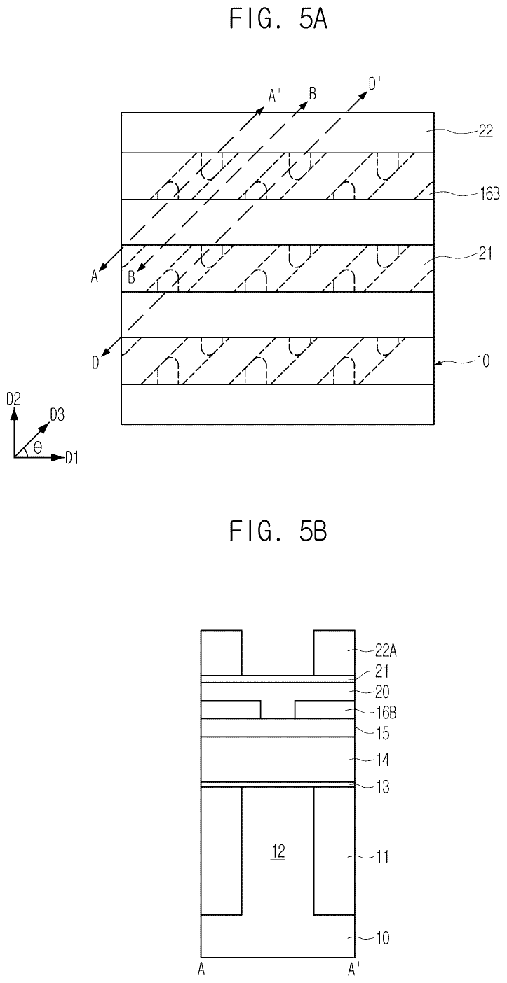

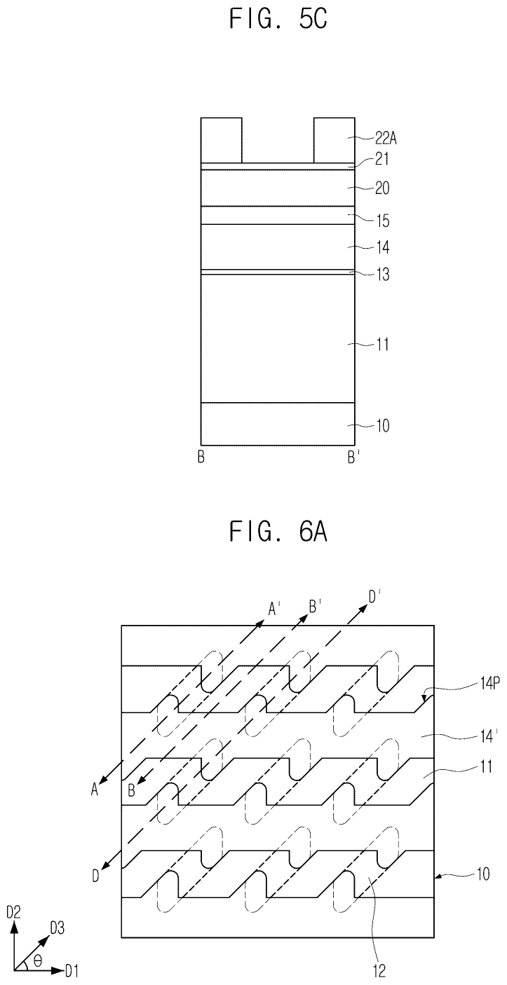

Referring to FIGS. 5A to 5C, a third hard mask layer 20 and a fifth mask layer 21 may be sequentially formed over the second mask pattern 16B and the first mask layer 15.

Subsequently, a sixth mask pattern 22A may be formed over the fifth mask layer 21.

The third hard mask layer 20 may be formed over the second mask pattern 16A and the first mask layer 15 to gap-fill between the second mask pattern 16A. The third hard mask layer 20 may be referred to as a ‘planarization layer’. The third hard mask layer 20 may function as an etching barrier for etching the second mask pattern 16A. The third hard mask layer 20 may include a material having an etching selectivity with respect to the second mask pattern 16A and the first mask layer 15. For example, the third hard mask layer 20 may include a carbon material. For example, the carbon material may include an amorphous carbon material. In particular, according to an embodiment of the present disclosure, the amorphous carbon material may include a low temperature amorphous carbon (LT-ACL) material. Here, the low temperature amorphous carbon material may refer to an amorphous carbon material that is formed at a low temperature of approximately 350° C. or lower, however the technical concepts and scope of the present disclosure may not be limited thereto.

The fifth mask layer 21 may function as an etching barrier for etching the third hard mask layer 20. The fifth mask layer 21 may include a dielectric material having an etching selectivity with respect to the third hard mask layer 20. The fifth mask layer 21 may be formed to be thinner than the third hard mask layer 20. For example, the fifth mask layer 21 may include a nitride material. For example, the nitride material may include silicon nitride or silicon oxynitride.

The sixth mask pattern 22A may function as an etching barrier for etching the fifth mask layer 21 and the third hard mask layer 20. The sixth mask pattern 22A may include a material having an etching selectivity with respect to the fifth mask layer 21 and the third hard mask layer 20. For example, the sixth mask pattern 22A may include a silicon material. For example, the silicon material may include polysilicon.

The sixth mask pattern 22A may extend in the first direction D1 to be spaced apart in the second direction D2. The sixth mask pattern 22A may define a trench region.

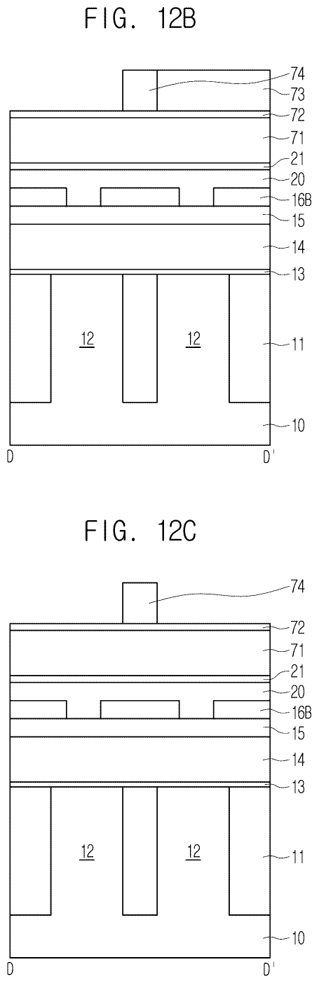

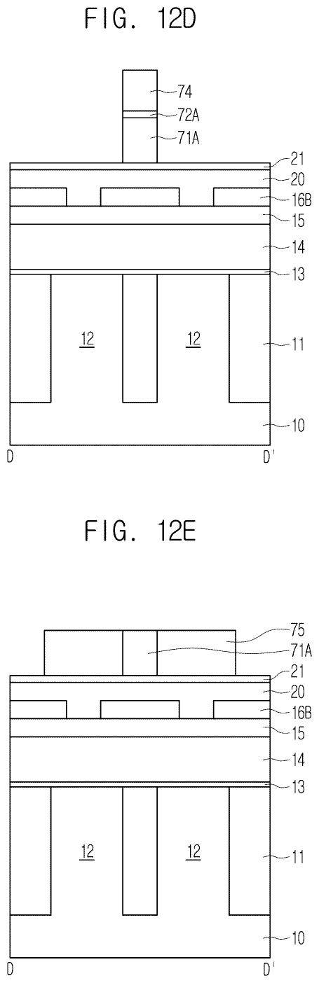

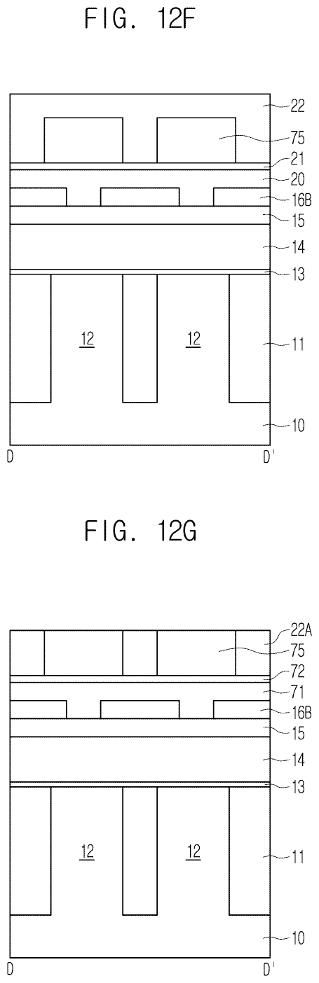

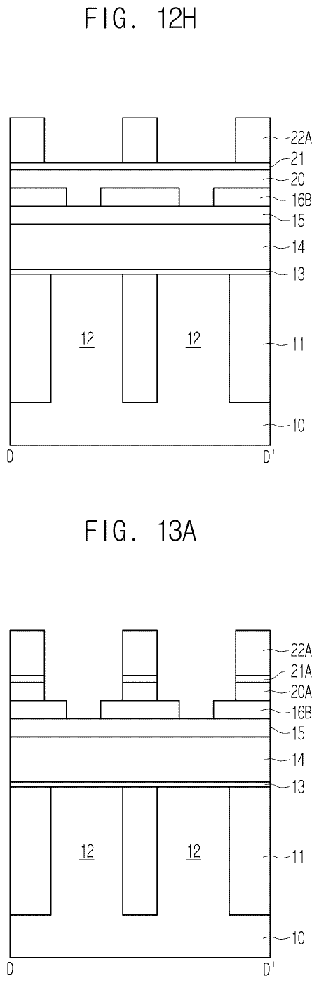

The process of forming the sixth mask pattern 22A will be described in detail below with reference to FIGS. 12A to 12H.

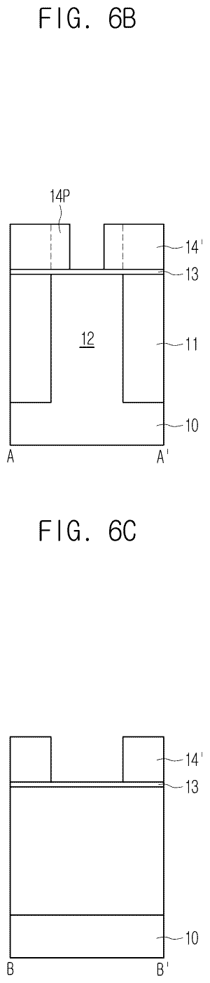

Referring to FIGS. 6A to 6C, the first hard mask pattern 14′ may be formed over the substrate 10.

The first hard mask pattern 14′ may extend in the first direction D1 to be spaced apart in the second direction D2. The first hard mask pattern 14′ may include a plurality of protrusions 14P. The protrusions 14P may be spaced apart from each other in the first direction D1. The protrusions 14P may include a first array where they are spaced apart from each other in the first direction D1 along a first side of the first hard mask pattern 14′, and a second array where they are spaced apart from each other in the first direction D1 along a second side of the first hard mask pattern 14′. The protrusions 14P of the first array and the second array may not be disposed on the same line extending in the second direction D2.

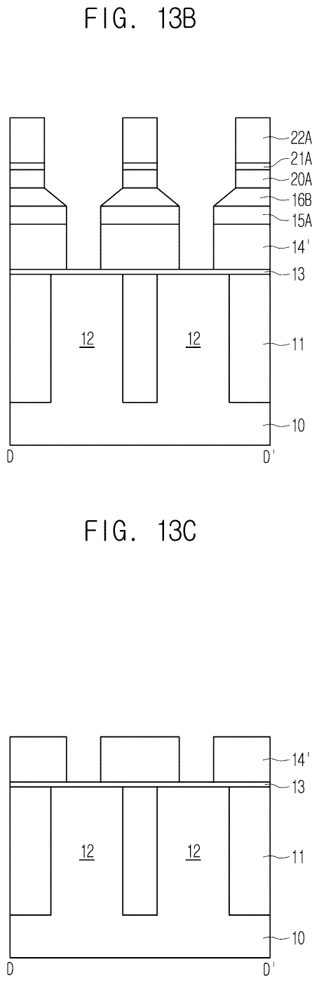

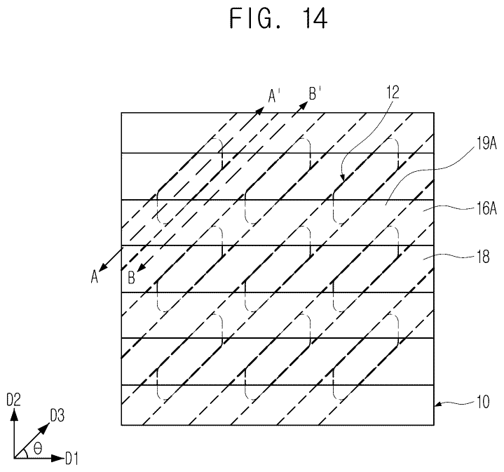

The process of forming the first hard mask pattern 14′ will be described in detail below with reference to FIGS. 13A to 13C.

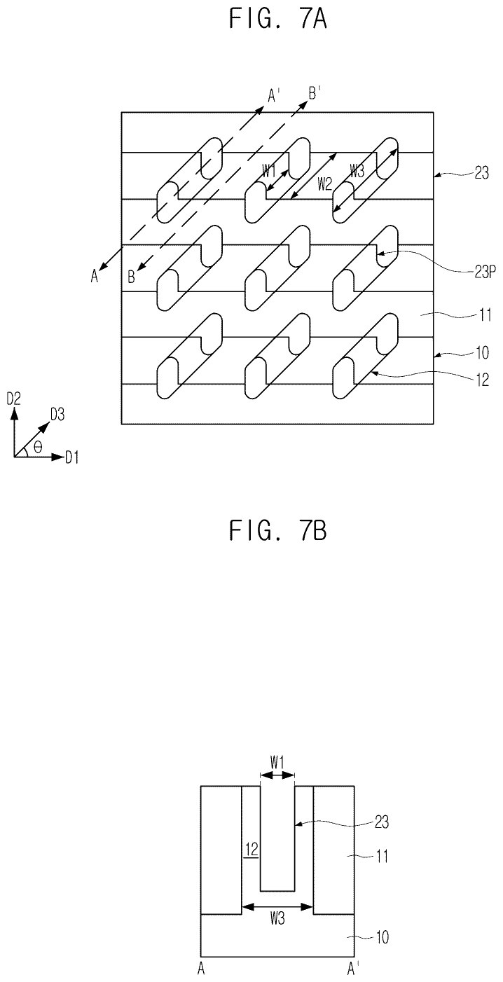

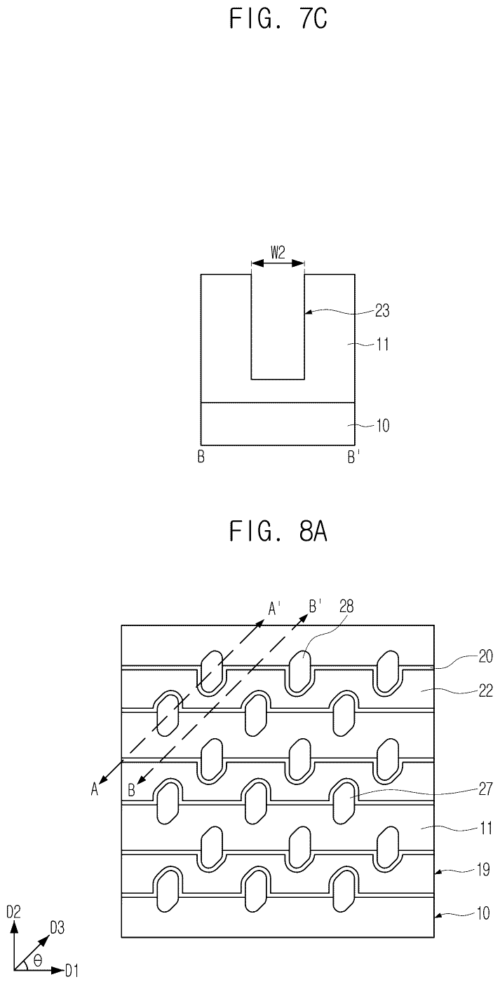

Referring to FIGS. 7A to 7C, a trench 23 may be formed to cross the active region 12 and the isolation layer 11 and to extend in the first direction D1.

The trench 23 may be formed through a series of the processes of etching the adhesive layer (13, see FIG. 6B) by using the first hard mask pattern 14′ as an etching barrier, and then etching the substrate 10 to a predetermined depth.

After the trench 23 is formed, the adhesive layer 13 and the first hard mask pattern 14′ may be removed.

The trench 23 may extend in the first direction D1 to be spaced apart in the second direction D2. The trench 23 may include a plurality of concave portions 23P. The concave portions 23P may be spaced apart from each other in the first direction D1. The concave portions 23P may include a first array where they are spaced apart from each other in the first direction D1 along a first side of the trench 23 and a second array where they are spaced apart from each other in the first direction D1 along a second side of the concave portions 23P.

Each of the concave portions 23P of the first array and the second array may not overlap in the second direction D2. The concave portions 23P may not be disposed on the same line extending in the second direction D2. Each of the concave portions 23P of the first array and the second array may overlap with each other in the third direction D3. The concave portions 23P may be disposed on the same line extending in the third direction D3. The concave portions 23P disposed on the same line in the third direction D3 may overlap with the active region 12.

In the third direction D3, the line width of the trench 23 may be different from the line width W1 of the trench 23 crossing the active region 12 and the line width W2 of the trench 23 crossing the isolation layer 11. The line width W1 of the trench 23 crossing the active region 12 may be narrower than the line width W2 of the trench 23 crossing the isolation layer 11. Also, all of the line widths W1 and W2 of the trench 23 crossing the active region 12 and the isolation layer 11 may be narrower than the line width W3 of the active region 12 in the longitudinal direction.

The trench 23 may cross the short axis direction of the active region 12.

One trench 23 may be formed in each active region 12. The trench 23 may cross the center of each active region 12. The trenches 23 may be spaced apart from each other in the second direction D2. The trench 23 may have a shallower depth than that of the isolation layer 11. The bottom surface of the trench 23 may be disposed at a higher level than the bottom surface of the isolation layer 11. According to another embodiment of the present disclosure, the bottom portion of the trench 23 may have a curvature. The trench 23 may be a space where a buried gate structure is formed, which may be referred to as a ‘gate trench 23’.

According to another embodiment of the present disclosure, the bottom surface of the trench of the isolation layer 11 may be additionally etched to form a fin. The channel width may be increased by the fin, improving the electrical characteristics.

According to an embodiment of the present disclosure, by forming the first hard mask pattern 14′ having a protrusion (14P, see FIG. 6A) that overlaps with both ends of the active region 12, that is, a junction region, the line width of the junction region forming the contact for electrical connection with the upper structure may be secured. According to an embodiment of the present disclosure, the line width of the junction region may be secured by as much as the difference (W2−W1) between the line width W2 of the trench 23 crossing the isolation layer 11 and the line width W1 of the trench 23 crossing the active region 12.

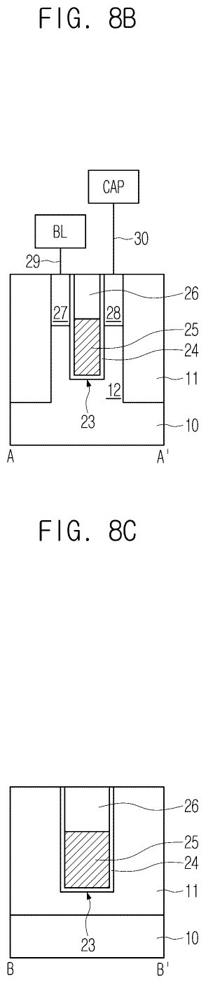

Referring to FIGS. 8A to 8C, a gate dielectric layer 24 may be formed to cover the inner side surface of the trench 23.

The gate dielectric layer 24 may be conformally formed on the bottom surface and inner side surface of the trench 23. The gate dielectric layer 24 may include silicon oxide, silicon nitride, silicon oxynitride, a high-k material, or a combination thereof. The high-k material may include a material having a dielectric constant which is greater than the dielectric constant of silicon oxide. For example, the high-k material may include a material having a dielectric constant which is greater than approximately 3.9. For another example, the high-k material may include a material having a dielectric constant which is greater than approximately 10. For yet another embodiment, the high-k material may include a material having a dielectric constant of approximately 10 to 30. The high-k material may include at least one metallic element. The high-k material may include a hafnium-containing material. The hafnium-containing material may include hafnium oxide, hafnium silicon oxide, hafnium silicon oxynitride, or a combination thereof. According to another embodiment of the present disclosure, the high-k material may include lanthanum oxide, lanthanum aluminum oxide, zirconium oxide, zirconium silicon oxide, zirconium silicon oxynitride, aluminum oxide, or a combination thereof. Other known high-k materials may be optionally used as the high-k material. The gate dielectric layer 24 may include a metal oxide.

Subsequently, a gate electrode 25 may be formed to fill a portion of the trench 23 over the gate dielectric layer 24.

The gate electrode 25 may be a low-resistance material for reducing the gate sheet resistance. The gate electrode 25 may include a semiconductor material, a metal-based material, or a combination thereof. The gate electrode 25 may include polysilicon, a metal, a metal nitride, or a combination thereof. For example, the gate electrode 25 may include N-type doped polysilicon, tantalum nitride (TaN), titanium nitride (TiN), tungsten (W), tungsten nitride (WN), molybdenum (Mo), ruthenium (Ru), or a combination thereof. According to another embodiment of the present disclosure, the gate electrode 25 may be formed of titanium nitride alone or molybdenum alone. According to yet another embodiment of the present disclosure, the gate electrode 25 may be formed of a stack of titanium nitride and tungsten (i.e., TiN/W) or a stack of titanium nitride and polysilicon (i.e., TiN/Polysilicon).

According to another embodiment of the present disclosure, the gate electrode 25 may comprise a dual gate structure including upper and lower gates. According to another embodiment of the present disclosure, the gate electrode 25 may comprise a triple gate structure including upper, middle, and lower gates.

According to another embodiment of the present disclosure, the gate electrode 25 may have a high work function. Here, the high work function may refer to a work function which is higher than the mid-gap work function of silicon. The low work function may refer to a work function which is lower than the mid-gap work function of silicon. For example, the high work function may have a work function which is higher than approximately 4.5 eV, and the low work function may have a work function which is lower than approximately 4.5 eV. The gate electrode 25 may include P-type polysilicon or nitrogen-rich titanium nitride (TiN).

According to another embodiment of the present disclosure, the gate electrode 25 may have an increased high work function. The gate electrode 25 may include a metal silicon nitride. The metal silicon nitride may be obtained by doping a metal nitride with silicon. The gate electrode 25 may include a metal silicon nitride with a controlled silicon content. For example, the gate electrode 25 may include tantalum silicon nitride (TaSiN) or titanium silicon nitride (TiSiN). Titanium nitride may have a high work function, and silicon may be contained in the titanium nitride to further increase the work function of the titanium nitride. The titanium silicon nitride may have a controlled silicon content to have an increased high work function. According to another embodiment of the present disclosure, the gate electrode 25 may include titanium aluminum nitride (TiAlN).

Subsequently, a capping layer 26 may be formed over the gate electrode 25 to fill the remaining portion of the trench 23.

The capping layer 26 may serve to protect the gate electrode 25. The capping layer 26 may fill the upper portion of the trench 23 over the gate electrode 25. The upper surface of the capping layer 26 may be disposed at the same level as the upper surfaces of the source and drain regions 27 and 28. The capping layer 26 may include a dielectric material. The capping layer 26 may include silicon nitride, silicon oxynitride, or a combination thereof. According to another embodiment of the present disclosure, the capping layer 26 may include a combination of silicon nitride and silicon oxide. The capping layer 26 may include a silicon nitride liner and a spin-on dielectric (SOD).

Subsequently, a source region 27 and a drain region 28 may be formed in the active region 12 on both sides of the trench 23. The source region 27 may be formed in the active region 12 on a first side surface of the trench 23, and a drain region 28 may be formed in the active region 12 on a second side surface of the trench 23.

The source and drain regions 27 and 28 may be the regions doped with a conductive dopant, respectively. For example, the conductive dopant may include phosphorus (P), arsenic (As), antimony (Sb), or boron (B). The source and drain regions 27 and 28 may be doped with dopants of the same conductive type. The source and drain regions 27 and 28 may be spaced apart from each other by the trench 23. The bottom surfaces of the source and drain regions 27 and 28 may be disposed at a predetermined depth from the top surface of the active region 12. The bottom surface of the source and drain regions 27 and 28 may be higher than the bottom surface of the trench 23. The source region 27 may be referred to as a ‘first doping region 27’ or a ‘first impurity region 27’, and the drain region 28 may be referred to as a ‘second doping region 28’ or a ‘second impurity region 28’.

As described above, according to an embodiment of the present disclosure, by forming the first hard mask pattern 14′ having a protrusion through a masking process for forming the active region 12, a trench 23 having a line shape with a concave portion may be formed. Therefore, the line widths of the source and drain regions 27 and 28 may be secured, thereby securing a Self-Aligned Contact (SAC) margin.

A buried gate structure including a gate dielectric layer 24, a gate electrode 25 and a capping layer 26 sequentially gap-filling the trench 23 may be formed. The buried gate structure may define a channel between the source and drain regions 27 and 28. The channel may be defined along the profile of the trench 23.

Subsequently, a bit line BL and a memory storage element CAP electrically connected to the substrate 10 may be formed sequentially. The bit line contact 29 may electrically connect the bit line BL to the source region 27, and the storage node contact 30 may electrically connect the memory storage element CAP to the drain region 28. The bit line BL and the memory storage element CAP may be disposed at a higher level than the buried gate structure. The bit line BL and the memory storage element CAP may be disposed at different levels. The memory storage element CAP may be disposed at a higher level than the bit line BL. The memory storage element CAP may include a capacitor. According to another embodiment of the present disclosure, the memory storage element CAP may be a thyristor, a phase change material, a magnetic tunnel junction (MTJ), or a variable resistance material.

According to an embodiment of the present disclosure, the semiconductor device may include a plurality of memory cells, and the neighboring memory cells may be separated from each other by the isolation layer 11. One memory cell may be formed over one active region 12, and this may be referred to as a ‘memory cell of a 1G1A (one Gate-one Active) structure.’ In the memory cell of the 1G1A structure, since the bit line BL is coupled to one active region 12, one memory cell may be coupled to one bit line BL. The memory cell of the 1G1A structure may include 1T1C (one Transistor-one Capacitor). As a comparative example, in a typical DRAM, two memory cells may be formed in one active region, and two gate electrodes may be formed in one active region, and two neighboring memory cells may share one bit line.

FIGS. 9A to 9I are cross-sectional views illustrating operations of a method for forming a second mask pattern 16A shown in FIG. 2A. FIGS. 9A to 9I are cross-sectional views taken along a line C-C′ shown in FIG. 2A

Referring to FIG. 9A, a first sacrificial layer 51, a second sacrificial layer 52, and a first photomask pattern 53 may be sequentially formed over the second mask layer 16.

The first and second sacrificial layers 51 and 52 may serve as etching barriers for etching the second mask layer 16. The first and second sacrificial layers 51 and 52 may include a dielectric material. For example, the first sacrificial layer 51 may include an amorphous carbon material. For example, the second sacrificial layer 52 may include silicon oxynitride. The thickness of the second sacrificial layer 52 may be thinner than the thickness of the first sacrificial layer 51.

The first photomask pattern 53 may be a photosensitive film pattern that is obtained by coating a photomask over the second sacrificial layer 52 and then performing a patterning process through exposure and development processes. The first photomask pattern 53 may be an ArF photosensitive film pattern, however the technical concepts and scope of the present disclosure may not be limited thereto.

Referring to FIG. 9B, a first spacer 54 may be formed on both sides of the first photomask pattern 53. The first spacer 54 may be formed through a series of the processes of forming a spacer material on the profile of the entire structure including the first photomask pattern 53 and then performing a spacer etching process.

The first spacer 54 may include a dielectric material having excellent step coverage characteristics so that it may be deposited uniformly. For example, the first spacer 54 may include an ULTO (Ultra Low Temperature Oxide) material, however the technical concepts and scope of the present disclosure may not be limited thereto.

Referring to FIG. 9C, the first photomask pattern (53, see FIG. 9B) may be removed. For example, the first photomask pattern 53 may be removed by an oxygen strip process or a cleaning process, however the technical concepts and scope of the present disclosure may not be limited thereto.

Accordingly, the first spacer 54 may remain over the second sacrificial layer 52.

Referring to FIG. 9D, first and second sacrificial patterns 51A and 52A may be formed. The first and second sacrificial patterns 51A and 52A may be formed through a series of the processes of using the first spacer 54 as an etching barrier and sequentially etching the second sacrificial layer (52, see FIG. 9C) and the first sacrificial layer (51, see FIG. 9C).

Referring to FIG. 9E, the second sacrificial pattern 52A and the first spacer 54 may be removed.

According to another embodiment of the present disclosure, the second sacrificial pattern 52A and the first spacer 54 may be completely removed by being lost at a moment when the etching process for forming the first sacrificial pattern 51A is completed.

Therefore, the first sacrificial pattern 51A may remain over the second mask layer 16.

Referring to FIG. 9F, a second spacer 55 may be formed on both sides of the first sacrificial pattern 51A. The second spacer 55 may be formed through a series of the processes of forming a spacer material on the profile of the entire structure including the first sacrificial pattern 51A and then performing a spacer etching process.

The second spacer 55 may include a dielectric material having excellent step coverage characteristics so that it may be deposited uniformly. The second spacer 55 may include the same material as that of the first spacer 54. For example, the second spacer 55 may include an ULTO (Ultra Low Temperature Oxide) material, however the technical concepts and scope of the present disclosure may not be limited thereto.

Referring to FIG. 9G, the first sacrificial pattern 51A may be removed.

Therefore, the second spacer 55 may remain over the second mask layer 16.

Referring to FIG. 9H, a second mask pattern 16A may be formed. The second mask pattern 16A may be formed by using the second spacer 55 as an etching barrier and etching the second mask layer (16, see FIG. 9G).

Referring to FIG. 9I, the second spacer (55, see FIG. 9H) may be removed.

Therefore, the second mask pattern 16A may remain over the first mask layer 15.

In particular, according to an embodiment of the present disclosure, in order to form the second mask pattern 16A, the same process as the line process for defining the long axis of the active region 12 may be performed. According to an embodiment of the present disclosure, the double spacer patterning technology (DSPT) in which the spacer patterning technology as illustrated in FIGS. 9B and 9F is performed twice may be performed. Also, since the photomask pattern 53 applied to FIG. 9A is also patterned with the same mask as the mask applied when the active region 12 is formed, it may not have to separately perform a masking process.

According to an embodiment of the present disclosure, the spacer patterning technology (SPT) may be performed as a positive SPT process. The positive SPT process may refer to a process of forming spacers on both sides of a sacrificial layer and then removing the sacrificial layer, leaving the spacers. The spacer patterning technology may form a spacer with a narrower line width than the line width of the first photomask pattern (53, see FIG. 9A) or the first sacrificial pattern (51A, see FIG. 9F), making it possible to define a finer line width.

In particular, according to an embodiment of the present disclosure, by performing the SPT process twice, it is possible to realize a line width which is finer than the minimum line width that may be formed by an exposure process. Also, lines may be formed uniformly.

FIGS. 10A to 10G are cross-sectional views illustrating operations of a method for forming a fourth mask layer 19 shown in FIG. 3A. FIGS. 10A to 10G are cross-sectional views taken along a line D-D′ shown in FIG. 3A.

Referring to FIG. 10A, a second hard mask layer 17 and a third mask layer 18 may be sequentially formed over the second mask layer 16. The second hard mask layer 17 and the third mask layer 18 may have the same structure as those of the second hard mask layer 17 and the third mask layer 18 illustrated in FIGS. 3A to 3C.

Subsequently, a third sacrificial layer 61, a fourth sacrificial layer 62, and a second photomask pattern 63 may be sequentially formed over the third mask layer 18.

The third and fourth sacrificial layers 61 and 62 may function as etching barriers for etching the third mask layer 18. The third and fourth sacrificial layers 61 and 62 may include a dielectric material. For example, the third sacrificial layer 61 may include an amorphous carbon material. For example, the fourth sacrificial layer 62 may include silicon oxynitride. The thickness of the fourth sacrificial layer 62 may be thinner than the thickness of the third sacrificial layer 61.

The second photomask pattern 63 may be a photosensitive film pattern that is formed by coating the upper portion of the fourth sacrificial layer 62 with a photomask and then performing a patterning process through exposure and development processes. The second photomask pattern 63 may be an ArF photosensitive film pattern, however the technical concepts and scope of the present disclosure may not be limited thereto.

Referring to FIG. 10B, a third spacer 64 may be formed on both sidewalls of the second photomask pattern 63. The third spacer 64 may be formed through a series of the processes of forming a spacer material on the profile of the entire structure including the second photomask pattern 63 and then performing a spacer etching process.

The third spacer 64 may include a dielectric material having excellent step coverage characteristics so that it may be deposited uniformly without forming any voids or gaps between the spacer and the underlying surface that is covered. A suitable material for the spacer 64 may include an ULTO (Ultra Low Temperature Oxide) material, however the technical concepts and scope of the present disclosure may not be limited thereto.

Subsequently, the second photomask pattern 63 may be removed. For example, the second photomask pattern 63 may be removed by an oxygen strip process or a cleaning process, however the technical concepts and scope of the present disclosure may not be limited thereto.

Referring to FIG. 10C, the third and fourth sacrificial patterns 61A and 62A may be formed. The first and second sacrificial patterns 61A and 62A may be formed through a series of the processes of sequentially etching the fourth sacrificial layer (62, see FIG. 10B) and the first sacrificial layer (61, see FIG. 10B) by using the third spacer 64 as an etching barrier.

Subsequently, the fourth sacrificial pattern 62A and the third spacer 64 may be removed.

According to another embodiment of the present disclosure, the fourth sacrificial pattern 62A and the third spacer 64 may all be removed by being lost at a moment when the etching process for forming the third sacrificial pattern 61A is completed.

Referring to FIG. 10D, the fourth spacer 65 may be formed on both sidewalls of the third sacrificial pattern 61A. The fourth spacer 65 may be formed through a series of the processes of forming a spacer material on the profile of the entire structure including the third sacrificial pattern 61A and then performing a spacer etching process.

The fourth spacer 65 may include a dielectric material having excellent step coverage characteristics so that it may be deposited uniformly. The fourth spacer 65 may include the same material as that of the third spacer 64. For example, the fourth spacer 65 may include an ULTO (Ultra Low Temperature Oxide) material, however the technical concepts and scope of the present disclosure may not be limited thereto.

Subsequently, the third sacrificial pattern 61A may be removed.

Referring to FIG. 10E, a fourth mask layer 19 that gap-fills between the fourth spacers 65 may be formed over the fourth spacers 65 and the third mask layer 18.

For example, the fourth mask layer 19 may include a silicon material. For example, the silicon material may include a polysilicon material.

Referring to FIG. 10F, a fourth mask pattern 19A may be formed. The fourth mask pattern 19A may be formed through a planarization process. The planarization process may be performed targeting the upper surface of the fourth spacer 65 to be exposed. For example, the planarization process may include an etch-back process or a Chemical Mechanical Polishing (CMP) process.

Referring to FIG. 10G, the fourth spacer (65, see FIG. 10F) may be removed.

Therefore, the fourth mask pattern 19A may remain over the third mask layer 18.

The fourth mask pattern 19A may have a line shape of a longitudinal direction extending in the second direction D2 and spaced apart in the first direction D1. The fourth mask pattern 19A may be a mask pattern whose shape and spacing distance are the same as those of the mask pattern applied for a line cut of the active region 12. The fourth mask pattern 19A may have a spacing position which is different from a spacing position of the mask pattern applied for the line cut of the active region 12. The fourth mask pattern 19A may be formed by the double spacer patterning technology (DSPT). The fourth mask pattern 19A may be formed by sequentially performing a positive SPT process and a negative SPT process. Here, the negative SPT process may refer to a process of forming a gap-fill layer that gap-fills between the spacer pattern that is formed through the positive SPT process and then leaving the gap-fill layer by removing the spacer pattern.

In particular, according to an embodiment of the present disclosure, a fourth mask pattern 19A with a uniform spacing distance may be formed by sequentially performing the positive SPT process and the negative SPT process.

FIGS. 11A to 11C are cross-sectional views illustrating operations of a method for forming a second mask pattern 16B shown in FIG. 4A. FIGS. 11A to 11C are cross-sectional views taken along a line D-D′ shown in FIG. 4A.

FIG. 11A is a cross-sectional view illustrating the processes that are continuously performed after the process of FIG. 10G.

Referring to FIG. 11A, a second hard mask pattern 17A and a third mask pattern 18A may be formed.

The second hard mask pattern 17A and the third mask pattern 18A may be formed by using the fourth mask pattern 19A as an etching barrier and sequentially etching the third mask layer 18 and the second hard mask layer 17.

Subsequently, the third mask pattern 18A and the fourth mask pattern 19A may be removed.

According to another embodiment of the present disclosure, the third mask pattern 18A and the fourth mask pattern 19A may all be removed by being lost at a moment when the etching process for forming the second hard mask pattern 17A is completed.

Referring to FIG. 11B, an island-shape second mask pattern 16B may be formed. The island-shape second mask pattern 16B may be formed by using the second hard mask pattern 17A as an etching barrier and etching the second mask pattern (16A, see FIG. 11A). The etched second mask pattern may be indicated by a reference numeral ‘16B’.

Referring to FIG. 11C, the second hard mask pattern 17A may be removed.

Therefore, the second mask pattern 16B may remain over the first mask layer 15.

FIGS. 12A to 12H are cross-sectional views illustrating operations of a method for forming a second hard mask layer 17 shown in FIG. 5A. FIGS. 12A to 12H are cross-sectional views taken along a line D-D′ shown in FIG. 5A.

Referring to FIG. 12A, a third hard mask layer 20 and a fifth mask layer 21 may be sequentially formed over the second mask pattern 16B. The third hard mask layer 20 and the fifth mask layer 21 may have the same structure as the structure of the third hard mask layer 20 and the fifth mask layer 21 illustrated in FIGS. 5A to 5C.

Subsequently, a fifth sacrificial layer 71, a sixth sacrificial layer 72, and a third photomask pattern 73 may be sequentially formed over the fifth mask layer 21.

The fifth and sixth sacrificial layers 71 and 72 may function as etching barriers for etching the fifth mask layer 21. The fifth and sixth sacrificial layers 71 and 72 may include a dielectric material. For example, the fifth sacrificial layer 71 may include an amorphous carbon material. For example, the sixth sacrificial layer 72 may include silicon oxynitride. The thickness of the sixth sacrificial layer 72 may be thinner than the thickness of the fifth sacrificial layer 71.

The third photomask pattern 73 may be a photosensitive film pattern that is obtained by coating a photomask over the sixth sacrificial layer 72 and then performing a patterning process through exposure and development processes. The third photomask pattern 73 may be an ArF photosensitive film pattern, however the technical concepts and scope of the present disclosure may not be limited thereto.

Referring to FIG. 12B, the fifth spacer 74 may be formed on both sidewalls of the third photomask pattern 73. Forming the fifth spacer 74 may include forming a spacer material on the profile of the entire structure including the third photomask pattern 73 and then performing a spacer etching process.

The fifth spacer 74 may include a dielectric material having excellent step coverage characteristics so that it may be deposited uniformly. For example, the fifth spacer 74 may include an ULTO (Ultra Low Temperature Oxide) material, however the technical concepts and scope of the present disclosure may not be limited thereto.

Referring to FIG. 12C, the third photomask pattern 73 may be removed. For example, the third photomask pattern 73 may be removed by an oxygen strip process or a cleaning process, however the technical concepts and scope of the present disclosure may not be limited thereto.

Therefore, the fifth spacer 74 may remain over the sixth sacrificial layer 72.

Referring to FIG. 12D, the fifth and sixth sacrificial patterns 71A and 72A may be formed. The fifth and sixth sacrificial patterns 71A and 72A may be formed through a series of the processes of using the fifth spacer 74 as an etching barrier and sequentially etching the sixth sacrificial layer (72, see FIG. 12C) and the fifth sacrificial layer (71, see FIG. 12C).

Subsequently, the sixth sacrificial pattern 72A and the fifth spacer 74 may be removed.

According to another embodiment of the present disclosure, the sixth sacrificial pattern 72A and the fifth spacer 74 may all be removed by being lost at a moment when the etching process for forming the fifth sacrificial pattern 71A is completed.

Referring to FIG. 12E, a sixth spacer 75 may be formed on both sidewalls of the fifth sacrificial pattern 71A. The sixth spacer 75 may be formed through a series of the processes of forming a spacer material on the profile of the entire structure including the fifth sacrificial pattern 71A and then performing a spacer etching process.

The sixth spacer 75 may include a dielectric material having excellent step coverage characteristics so that it may be deposited uniformly. The sixth spacer 75 may include the same material as that of the fifth spacer 74. For example, the sixth spacer 75 may include an ULTO (Ultra Low Temperature Oxide) material, however the technical concepts and scope of the present disclosure may not be limited thereto.

Subsequently, the fifth sacrificial pattern 71A may be removed.

Referring to FIG. 12F, a sixth mask layer 22 may be formed over the sixth spacers 75 to gap-fill between the sixth spacers 75 and the fifth mask layer 21.

For example, the sixth mask layer 22 may include a silicon material. For example, the silicon material may include a polysilicon material.

Referring to FIG. 12G, a sixth mask pattern 22A may be formed. The sixth mask pattern 22A may be formed through a planarization process. The planarization process may be performed targeting to expose the upper surface of the sixth spacers 75. For example, the planarization process may include an etch-back process or a Chemical Mechanical Polishing (CMP) process.

Referring to FIG. 12H, the sixth spacer (75, see FIG. 12G) may be removed.

Therefore, the sixth mask pattern 22A may remain over the fifth mask layer 21.

The sixth mask pattern 22A may be formed through the double spacer patterning technology (DSPT). The sixth mask pattern 22A may be formed by sequentially performing a positive SPT process and a negative SPT process.

In particular, according to an embodiment of the present disclosure, the sixth mask pattern 22A with a uniform spacing may be formed by sequentially performing the positive SPT process and the negative SPT process.

FIGS. 13A to 13C are cross-sectional views illustrating operations of a method for forming the first hard mask pattern 14′ shown in FIG. 6A. FIGS. 13A to 13C are cross-sectional views taken along a line D-D′ shown in FIG. 6A.

FIG. 13A may be a cross-sectional view illustrating the processes that are continuously performed after the process of FIG. 12H.

Referring to FIG. 13A, a third hard mask pattern 20A and a fifth mask pattern 21A may be formed.

The third hard mask pattern 20A and the fifth mask pattern 21A may be formed by using the sixth mask pattern 22A as an etching barrier and sequentially etching the fifth mask layer 21 and the third hard mask layer 20.

The area that is open by the third hard mask pattern 20A may be wider than the area that is open by the second mask pattern 16B.

Referring to FIG. 13B, a first hard mask pattern 14′ and a second mask pattern 15A of a line type extending in the first direction D1 may be formed.

In the third direction D3 crossing the active region 12, the first hard mask pattern 14′ that maintains the spacing distance between the second mask pattern 16B may be formed by the second mask pattern 16B.

Referring to FIG. 6C, the first hard mask pattern 14′ may maintain the same spacing distance as that of the third hard mask pattern 20A.

Referring to FIG. 13C, the sixth mask pattern (22A, see FIG. 13B), the fifth mask pattern (21A, see FIG. 13B), the third hard mask pattern (20A, see FIG. 13B), the second mask pattern (16B, see FIG. 13B), and the first mask pattern (15A, see FIG. 13B) may be removed.

Accordingly, the first hard mask pattern 14′ may remain over the adhesive layer 13.

According to an embodiment of the present disclosure, the process difficulty may be reduced when a wave-shaped buried gate is formed.

According to an embodiment of the present disclosure, the SAC margin may be improved by increasing the width of a junction region.

While the embodiments of the present disclosure have been described with respect to the specific embodiments, it will be apparent to those skilled in the art that various changes and modifications may be made without departing from the technical concepts and scope of the disclosure as defined in the following claims. Furthermore, the embodiments may be combined to form additional embodiments.

What is claimed is:

1. A method for fabricating a semiconductor device, the method comprising:
forming an isolation layer over a substrate and a plurality of active regions defined by the isolation layer;
forming a first hard mask pattern having a protrusion extending in a first direction over the substrate and overlapping with both ends of the active regions;
forming a trench having a plurality of concave portions crossing the active regions and the isolation layer in the first direction and overlapping with the active regions by etching the substrate with the first hard mask pattern used as an etching barrier; and
forming a buried gate structure to gap-fill the trench,
wherein the active regions are disposed in a first direction and a second direction which is orthogonal to the first direction and tilted in a third direction which is diagonal to the first and second directions.

2. The method of claim 1, wherein forming the first hard mask pattern includes:
forming a first hard mask layer over the substrate;
forming a first mask pattern having a line shape extending in the third direction over the first hard mask layer;
forming a second mask pattern having a line shape extending in the second direction and spaced apart in the first direction over the first mask pattern;
forming an island-shape first mask pattern overlapping with both ends of the active regions that are adjacent to each other in the third direction by etching the line-shaped first mask pattern with the second mask pattern;
forming a third mask pattern having a line shape extending in the first direction and spaced apart in the second direction over the island-shape first mask pattern; and
forming a first hard mask pattern having a protrusion extending in the first direction and overlapping with both ends of the active region by etching the first hard mask layer with the third mask pattern and the island-shape first mask pattern.

3. The method of claim 1, wherein forming the first hard mask pattern includes:
forming a first mask pattern of a line shape extending in the third direction over the first hard mask layer;
forming a second mask pattern of a line shape extending in the first direction and spaced apart in the second direction over the first mask pattern;
forming an island-shape first mask pattern overlapping with both ends of the active regions that are adjacent to each other in the third direction by etching the line-shaped first mask pattern with the second mask pattern;
forming a third mask pattern of a line type extending in the first direction and spaced apart in the second direction over the island-shape first mask pattern; and
forming a first hard mask pattern having a protrusion extending in the first direction and overlapping with both ends of the active region by etching the first hard mask layer with the third mask pattern and the island-shape first mask pattern.

4. The method of claim 1, wherein the protrusions are spaced apart from each other in the first direction along a first side and a second side of the first hard mask pattern.

5. The method of claim 4, wherein the protrusion on the first side of the first hard mask pattern and the protrusion on the second side of the first hard mask pattern are not disposed on the same line extending in the second direction.

6. The method of claim 1, wherein the concave portions are spaced apart from each other in the first direction along a first side and a second side of the trench.

7. The method of claim 6, wherein the concave portions on the first and second sides of the trench are not disposed on the same line extending in the second direction.

8. The method of claim 6, wherein the concave portions on first and second sides of the trench are disposed on the same line extending in the third direction that is non-orthogonal to the first and second directions.

9. The method of claim 2, wherein the first to third mask patterns include a silicon material.

10. The method of claim 2, wherein forming the first to third mask patterns includes using Double Spacer Patterning technology.

11. The method of claim 2, wherein forming the first mask pattern includes a Positive Spacer Patterning technology that is performed twice.

12. The method of claim 2, wherein forming the second and third mask patterns includes a Positive Spacer Patterning technology and a Negative Spacer Patterning technology.

13. The method of claim 1, wherein a line width of the trench overlapping with the isolation layer is greater than a line width of the trench overlapping with the active region.

14. The method of claim 1, wherein the trench is disposed one by one in each of the active regions.

15. The method of claim 1, wherein
after forming the buried gate structure,
the substrate is doped with an impurity to form a source region in the active region on a first side of the buried gate structure and to form a drain region in the active region on a second side of the buried gate structure.

16. The method of claim 1, wherein the trench has a wavy line shape extending in the first direction.

17. A method for fabricating a semiconductor device, the method comprising:
forming a plurality of active regions over a substrate;
forming a first hard mask pattern having protrusions extending in a first direction over the substrate and overlapping with both ends of the active regions;
forming a trench having a plurality of concave portions overlapping with the active regions; and
forming a buried gate structure to gap-fill the trench,
wherein the active regions are disposed in first and second directions and are extending in a third direction which is non-orthogonal to the first and second directions.
